(19) United States
(12) Patent Application Publication
(10) Pub. No.: US 2026/0265494 A1
(43) Pub. Date: Sep. 10, 2026

(54) ENGINEERING PLASTICS INCORPORATING CARBON FIBERS AND CARBON NANOTUBES FOR TUNED PERFORMANCE CHARACTERISTICS

(71) Applicant: Seagate Technology LLC, Fremont, CA (US)

(72) Inventors: Michael Yi Zhao Yao, Singapore (SG); Alvin Nathanael Soi Heng Koh, Singapore (SG); Daniel Raymond Stevens, Longmont, CO (US); Nopchanok Suksiri, Samutprakarn (TH); Apichart Devahastin, Bangkok (TH); Charuwan Rojanathavorn, Bangkok (TH); Natchapon Leungpakorn, Bangkok (TH); Jakkrathip Thippairote; Silapawat Treekaew, Korat (TH); Supattra Yothee, Samut Prakan (TH); Peeraphat Nualpetch, Bangkok (TH)

(21) Appl. No.: 19/069,489

(22) Filed: Mar. 4, 2025

(51) Int. Cl. C08K 7/06; B29C 33/42; B29K 307/04; B29L 31/00; B29L 31/34; B65D 1/36; B65D 65/38; B65D 81/26; C08J 3/20; C08K 3/04; H05K 13/00

(52) U.S. Cl. CPC C08K 7/06; B29C 33/42; B65D 1/36; B65D 65/38; B65D 81/261; C08J 3/203; C08K 3/041; C08K 3/042; C08K 3/046; H05K 13/0084; B29K 2307/04; B29L 2031/3481; B29L 2031/712; C08J 2371/10; C08K 2201/011

(57) ABSTRACT

Disclosed are composite injection moldable and thermoformable materials that may be used for making carriers (such as trays, packaging, and so forth) for carrying, cleaning, storing, and/or shipping electronic components or devices, as well as to the carriers made from such materials. In accordance with various aspects, the materials may be composed of an engineering plastic or blend and a hybrid filler. The hybrid filler combines tuned amounts of carbon fibers and carbon nanotubes to achieve desired properties while using a total amount of filler that is less than what would be needed to achieve the same properties using only carbon fibers. Moreover, the surfaces of the carriers can be roughened in a way that forms resin-rich islands that are devoid of carbon fibers and therefore less susceptible to peeling or flaking.

This disclosure relates to composite materials including engineering plastics that include carbon fiber and/or carbon nanotube fillers.

### SUMMARY

In accordance with certain aspects, the present disclosure describes composite materials that include an engineering plastic matrix, a carbon fiber filler dispersed in the engineering plastic matrix and present in an amount to provide a desired stiffness and, and a carbon nanotube filler dispersed in the engineering plastic matrix and present in an amount to provide a surface resistivity in a dissipative range. The fillers are present in a combined amount that is insufficient to cause surface peeling or flaking from the composite material.

In certain aspects, the carbon fiber filler is present in an amount of 5% to 20% by weight in the composite material and provides a flexural modulus for stiffness that is greater than about 10,000 MPa.

In certain aspects, the carbon nanotube filler is present in an amount of 0.1% to 8% by weight in the composite material and provides a surface resistivity in the dissipative range, for example between about 1×10⁴ ohms and 9.9×10¹¹ ohms, or between about 1×10⁴ ohms and 9.9×10⁵ ohms.

In accordance with certain aspects, the present disclosure describes molded trays for containing electronic components in a plurality of pockets, the molded tray being formed from the above-described composite materials. In certain aspects, the molded trays have roughened surfaces characterized by resin-rich islands that are substantially devoid of carbon fibers. In certain aspects, the molded trays include through holes extending from the pockets to an exterior surface of the molded tray, for example to facilitate liquid drainage or vacuum suction.

In accordance with certain aspects, the present disclosure describes methods for making molded trays for containing electronic components in a plurality of pockets. Such methods may include blending a composite material that includes a resin composed of an engineering plastic matrix, a first filler dispersed in the engineering plastic matrix, the first filler including carbon fibers present in an amount to provide a desired stiffness and insufficient to provide a surface resistivity in the dissipative range, and a second filler dispersed in the engineering plastic matrix, the second filler including carbon nanotubes present in an amount to provide a surface resistivity in the dissipative range, and where the first filler and the second filler are present in a combined amount that is insufficient to cause surface peeling or flaking from the composite material. Such composite material is then molded to form the molded tray. In certain aspects, molding can be performed using a mold having a roughened surface, the roughened surface configured to impart resin-rich islands on surfaces of the molded trays.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1A is a schematic top view of a molded tray that may be formed from composite materials in accordance with the present disclosure.

FIG. 1B is a schematic side view of the tray shown in FIG. 1A, taken along line 1B.

FIG. 1C is a schematic magnified view of the microscopic structure of a portion of the molded tray of FIG. 1B that is indicated by area 1C, the tray being formed from composite materials in accordance with the present disclosure.

FIG. 2 is a flow chart that depicts steps that may be performed in the blending of a composite material in accordance with the present disclosure, and in the formation of a molded tray from such composite material.

### DETAILED DESCRIPTION

The present disclosure relates to composite injection moldable and thermoformable materials that may be used for making carriers (such as trays, packaging, and so forth) for carrying or transporting electronic components or devices, as well as to the carriers made from such materials. In accordance with various aspects, the materials may be composed of an engineering plastic or blend and a hybrid filler. The hybrid filler combines tuned amounts of carbon fibers and carbon nanotubes to achieve desired properties while using a total amount of filler that is less than what would be needed to achieve the same properties using only carbon fibers.

Molded and thermoformed plastics are often used to make trays and carriers for transporting electronic devices and components. Filler materials may be used to impart certain characteristics and properties in the finished molded items, including reduced weight, increased strength or stiffness, sufficient surface conductivity to dissipate static and prevent electrostatic discharge (ESD), and so forth. In accordance with various aspects of the present disclosure, a combination of filler materials may be used that includes carbon fibers (CF) present in an amount that imparts desired stiffness without leading to undesired brittleness and flaking, and also includes carbon nanotubes (CNT) present in an amount that imparts desired surface resistivity in the static dissipative range. By independently tuning the amount of CF for physical properties without reliance on the CF filler for electrostatic properties, and tuning the amount of CNT present to impart desired electrostatic properties, the desired benefits of the filler materials can be realized without introducing deleterious effects such as surface flaking that may occur when CF and/or CNT are added in greater amounts.

In conventional applications, CFs are used as a filler for moldable engineering plastics. For example, CFs may be typically added to polyether ether ketone (PEEK) in an amount of about 25% to 45% by weight. This amount of CF loading can produce areas where carbon fibers accumulate near a surface, resulting in thin areas of resin that can peel or flake. When such material is used as a tray or carrier for electronic components, those flakes can be transferred to the components and potentially cause reliability issues. As used throughout this document, the terms tray, carrier, packaging, and the like may be used synonymously to refer to any type of component carrier that is designed for containing one or more components for transport between process stations, for shipping, for component cleaning, for staging, for temporary storage, and so forth. It will be appreciated that the use of one such term is non-limiting and does not preclude other terms or other uses.

In accordance with the present disclosure, it is recognized that, by using a hybrid filler for engineering plastics where the filler combines CFs with CNTs, the amount of CFs and the amount of CNTs can be individually tuned to provide different properties while at the same time reducing the total weight percentage of all fillers, thereby reducing the occurrence of surface peeling and flaking. For example, when molding a tray for carrying electronic components, CF and CNT can be added as fillers to PEEK to produce a desired target stiffness (for example, a flexural modulus greater than about 10,000 MPa), a target heat deflection temperature under load (for example, heat deflection temperature HDT of greater than about 220° C. under 1.8 MPa load), and a target surface resistance range (for example, in a range of about 1×10⁴ ohms to 9.9×10¹¹ ohms). To accomplish this, the CF filler may be present in an amount from about 5% to 20% by weight, and the CNT filler may be present in an amount from about 0.1% to 8% by weight. These amounts represent a reduction from what may be used conventionally, and thereby result in reduced surface peeling and flaking.

In certain embodiments, engineering polymer resins may include, but are not limited to, polyether ether ketone (PEEK), liquid crystal polymer (LCP), polyphenylene sulfide (PPS), polycarbonate (PC), polysulfone (PSU), polyetherimide(PEI), polyoxymethylene (POM), polyamide (Nylon), polyethylene terephthalate (PET), polybutylene terephthalate (PBT), and combinations thereof. For the CF filler, long carbon fibers, short carbon fibers, and combinations thereof may be used. For the CNT filler, various sizes of carbon nanotubes, graphene, carbon nanofibers, and combinations thereof may be used.

Moreover, it has been found that imparting a surface roughness to a molded material can reduce stiction between the molded carrier and the parts being carried, primarily by reducing the surface area over which the carrier and the parts are in contact. However, when CF is used as a filler material, the inclusion of CF within protrusions of the roughened surface structure can lead to flaking. As such, in accordance with various aspects, the present disclosure provides for imparting a surface roughness in a manner that prevents CF from entering the pockets that form the protrusions, thus producing material islands that are resin-rich and substantially devoid of CF, which leads to a decreased risk of surface flaking. This may involve imparting a surface roughness on the molded carrier having a characteristic dimension that is smaller than the average size of the carbon fibers in the CF filler.

Reference will now be made to the drawings, which depict one or more aspects described in this disclosure. However, it will be understood that other aspects not depicted in the drawings fall within the scope of this disclosure. Like numbers used in the figures refer to like components, steps, and the like. However, it will be understood that the use of a reference character to refer to an element in a given figure is not intended to limit the element in another figure labeled with the same reference character. In addition, the use of different reference characters to refer to elements in different figures is not intended to indicate that the differently referenced elements cannot be the same or similar. It will also be appreciated that the drawings are meant to illustrate certain aspects and arrangements of features in a way that contributes to their understanding and are not meant to be scale drawings that accurately represent size or shape of elements.

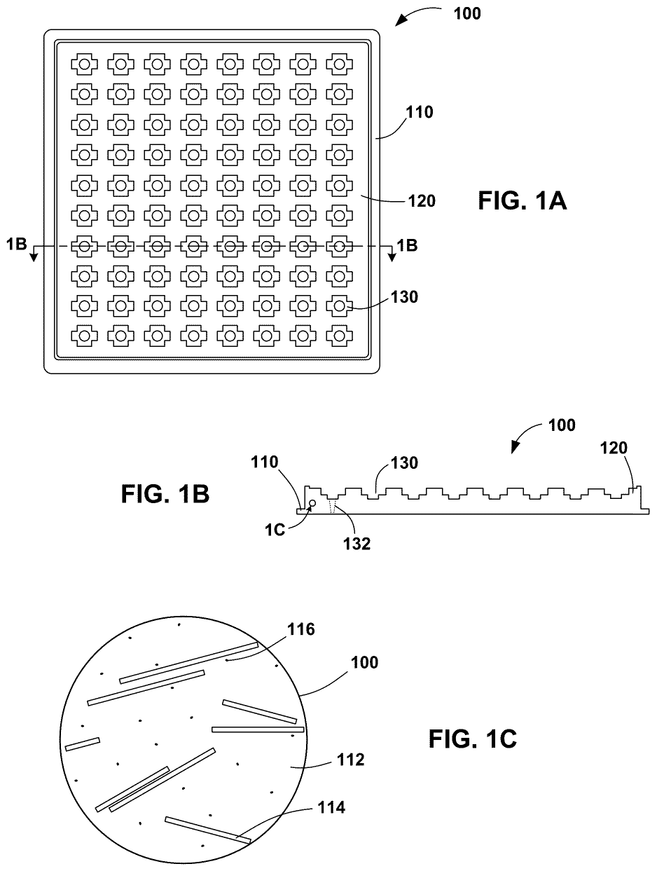

FIG. 1A is a schematic top view of an example electronic component tray 100 for containing electronic components (not shown). The tray 100 may be formed to have a base 110 and a raised carrier portion 120 that includes a plurality of pockets 130 that may be shaped to hold individual components. The tray 100 may be formed, for example by injection molding, out of a composite material in accordance with the present disclosure. That is, the tray 100 may be formed from a composite of an engineering plastic, a CF filler present in an amount to provide a desired stiffness, a CNT filler present in an amount to provide a desired surface resistivity, and a combined filler amount selected to reduce surface peeling or flaking. FIG. 1B shows a schematic side view of tray 100 taken along line 1B in FIG. 1A, illustrating a possible configuration of the pockets 130 for holding electronic components. Pockets 130 are shaped to suitably contain the electronic components for the given application. Optionally, through holes such as through hole 132 may be formed between pockets 130 and the bottom of base 110, for example to facilitate the draining of liquid during washing processes, the application of vacuum suction, and so forth. It will be recognized that the dimensions of tray 100, including base 110, raised carrier portion 120, and pockets 130, are not to scale.

FIG. 1C represents a schematic illustration of the material of tray 100 at a microscopic scale, for example taken from the area of tray 100 that is marked as 1C in FIG. 1B. While not to scale, FIG. 1C illustrates that the material of tray 100 includes carbon fibers 114 and carbon nanotubes 116 dispersed in a matrix 112 composed of an engineering plastic, which may be made from a single resin or a blend of resins, and which may include other filler materials that are not indicated.

An example use for an electronic component tray, such as tray 100, is for containing hard disk drive (HDD) components. HDD component trays are typically either thermoformed trays, which are usually used once for shipment of components, or injection molded trays, which are rigid and more expensive than thermoformed trays and usually used for many cycles. Injection molded trays may often be used as shipment trays that are also used as process trays. Injection molded trays are typically made of PEEK with CF added as a filler, or polycarbonate (PC) with carbon black and glass fibers added as fillers. These fillers are generally added to increasing stiffness, increasing tensile strength, improving heat deflection, improving electrical conductivity, and reduce costs (although glass fibers cannot improve electrical conductivity). As previously noted, high CF loading can result in peeling and flaking of resin, particularly in areas where accumulation of CF is at or near the surface. Such peeling and flaking may be more prominent after multiple uses, for example dozens to hundreds of use and washing cycles. Such peeling and flaking can cause component reliability issues, particularly when small flakes come off on the tray and onto the components when the components are placed in and removed from the tray. It should be noted that similar issues can appear with the use of other fillers.

As appreciated by the present disclosure, if only CFs are used as the filler for engineering plastics in the formation of electronic component trays, then the amount of CFs needed to impart the desired stiffness and achieve the target surface resistance will generally be in the range of 25% to 45% by weight. This relatively large amount can lead to carbon fiber bundling near the surface of the formed trays, which can result in peeling and flaking of resin. If only CNTs are used as the filler for engineering plastics in the formation of electronic component trays, then the amount of CNTs needed to impart the desired stiffness is high enough to result in a very low surface resistance, changing the material characteristics from dissipative to conductive. For certain electronic components that are ESD sensitive, contact with such a conductive surface while in the presence of an electrostatic field may cause an ESD event to occur that can damage the component.

Carbon fibers generally have sizes in the range of microns to tens or even hundreds of microns. Carbon fibers are made up of interlocking sheets of graphene and have a notably high tensile strength and stiffness. To create a carbon fiber composite material, carbon fibers are introduced into a melt that is composed of a polymer or polymer blend, such as an epoxy resin or other resin. The resulting mixture can be extruded, molded, thermoformed, and so forth, to create structures that may be useful as carriers, trays, and packaging. These composite materials are much stronger and stiffer than the polymer alone would have been.

Carbon nanotubes are cylindrical tubes of carbon atoms that are roughly 1000 times smaller than carbon fibers, having sizes on the order of nanometers to tens of nanometers. Nanotubes consist of carbon atoms bonded to one another in repeating hexagonal patterns to create a hollow cylinder that may be single-walled or multi-walled. Carbon nanotubes exhibit a high electrical conductivity, which makes them useful for electrical and electrostatic purposes. Carbon nanotubes also exhibit good thermal conductivity, which allows them to be used for heat transfer in polymers and other materials.

For ESD control, it is important for an electronic component tray or carrier to have a surface resistance that is in the dissipative range, which for the purposes of the present disclosure will be considered to be about 1×10⁴ ohms to about 9.9×10¹¹ ohms. This is sufficiently conductive to remove electrostatic charges when grounded. Below 1×10⁴ ohms is considered conductive, and above 1×10¹¹ ohms is considered insulative (although in certain aspects of the present disclosure, a surface resistance up to 9.9×10¹¹ ohms may be targeted).

In accordance with the present disclosure, CFs and CNTs are used as fillers in engineering plastics, with the CFs present in an amount tuned to provide a target stiffness and the CNTs present in an amount turned to provide a target surface resistance, and where the total weight percentage of all fillers is tuned to reduce the risk of peeling and flaking. For example, 5% to 20% by weight of CF may be used in an engineering plastic such as PEEK to achieve a flexural modulus greater than about 10,000 MPa. To achieve a surface resistance in the dissipative range, for example about 1×10⁴ ohms to 9.9×10¹¹ ohms, the CNT filler may be present an amount from about 0.1% to 8% by weight. These CF and CNT amounts may produce a heat deflection temperature of greater than about 220° C. under 1.8 MPa load, while also producing reduced surface peeling and flaking. With these properties, injection molded component trays can stand repeated use, washing, and handling, including exposure to temperatures of 120° C.

Component trays made exhibit stiction between the surface of the trays and the components being contained. In certain applications, the surface of the trays may be roughened to reduce the amount of stiction. However, surface roughening can lead to increase peeling and flaking issues, particularly when CFs are uses as a filler. The occurrence of peeling and flaking can be significantly reduced or eliminated by producing a surface roughness that creates resin rich islands, or protrusions, that are substantially devoid of CF. A surface roughness having dimensions that are less than the average size of the CF filler material will result in maintaining the CFs buried more deeply beneath the resin rich islands surfaces. The rough surfaces may be made by creating rough mold surface using electrical discharge machining (EDM) in the areas of the tray pockets, particularly where the components will have direct contact with the tray surface.

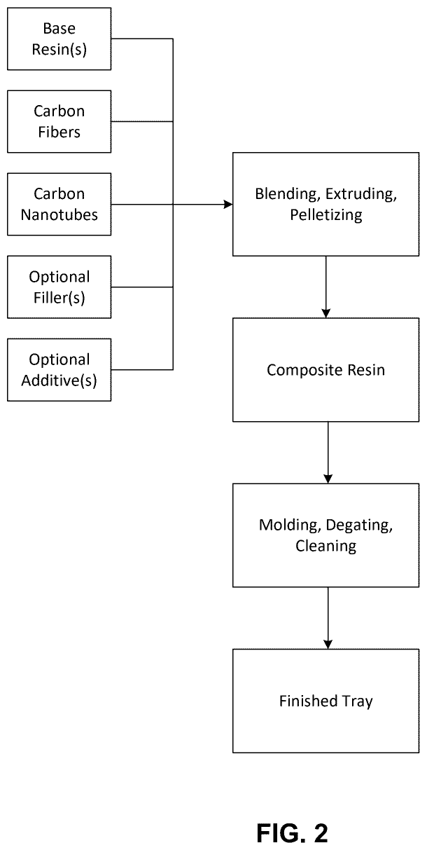

FIG. 2 shows a flow chart that includes steps that may be performed in the blending of a composite resin in accordance with the present disclosure, and then using that resin to form a molded item such as an electronic component tray. A base resin, or blend of base resins, along with carbon fibers, carbon nanotubes, and other optional fillers and additives may be blended, extruded, and pelletized. The resulting composite resin pellets include carbon fibers present in an amount that is tuned to provide a desired stiffness, and include carbon nanotubes present in an amount that is tuned to provide a desired surface resistivity in the dissipative range. These pellets of composite resin can then be heated and molded, for example by injection molding, into the final shape of the finished component tray or other molded item. The molded item can be degated, cleaned, and so forth to produce the finished item ready for use. As described above, the mold used for molding the composite material may be imparted with a surface roughness that allows resin-rich islands to be formed that are substantially devoid of carbon fibers, thereby reducing or eliminating any peeling and flaking of resin due to surface structure.

It should be understood that various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (for example, all described acts or events may not be necessary to carry out the techniques). In addition, while certain aspects of this disclosure are described as being performed by a single module or unit for purposes of clarity, it should be understood that the techniques of this disclosure may be performed by a combination of units or modules.

All scientific and technical terms used herein have meanings commonly used in the art unless otherwise specified. The definitions provided herein are to facilitate understanding of certain terms used frequently herein and are not meant to limit the scope of the present disclosure.

As used herein, the term “configured to” may be used interchangeably with the terms “adapted to” or “structured to” unless the content of this disclosure clearly dictates otherwise.

As used herein, the term “or” refers to an inclusive definition, for example, to mean “and/or” unless its context of usage clearly dictates otherwise. The term “and/or” refers to one or all of the listed elements or a combination of at least two of the listed elements.

As used herein, the phrases “at least one of” and “one or more of” followed by a list of elements refers to one or more of any of the elements listed or any combination of one or more of the elements listed.

As used herein, the terms “coupled” or “connected” refer to at least two elements being attached to each other either directly or indirectly. An indirect coupling may include one or more other elements between the at least two elements being attached. Further, in one or more embodiments, one element “on” another element may be directly or indirectly on and may include intermediate components or layers therebetween. Either term may be modified by “operatively” and “operably,” which may be used interchangeably, to describe that the coupling or connection is configured to allow the components to interact to carry out described or otherwise known functionality. For example, a controller may be operably coupled to a resistive heating element to allow the controller to provide an electrical current to the heating element.

As used herein, any term related to position or orientation, such as “proximal,” “distal,” “end,” “outer,” “inner,” and the like, refers to a relative position and does not limit the absolute orientation of an embodiment unless its context of usage clearly dictates otherwise.

The singular forms “a,” “an,” and “the” encompass embodiments having plural referents unless its context clearly dictates otherwise.

As used herein, “have,” “having,” “include,” “including,” “comprise,” “comprising” or the like are used in their open-ended sense, and generally mean “including, but not limited to.” It will be understood that “consisting essentially of,” “consisting of,” and the like are subsumed in “comprising,” and the like.

Reference to “one embodiment,” “an embodiment,” “certain embodiments,” or “some embodiments,” etc., means that a particular feature, configuration, composition, or characteristic described in connection with the embodiment is included in at least one embodiment of the disclosure. Thus, the appearances of such phrases in various places throughout are not necessarily referring to the same embodiment of the disclosure. Furthermore, the particular features, configurations, compositions, or characteristics may be combined in any suitable manner in one or more embodiments.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the disclosure.

What is claimed is:

1. A composite material comprising:
an engineering plastic matrix;
a first filler dispersed in the engineering plastic matrix, the first filler comprising carbon fibers present in an amount to provide a desired stiffness and insufficient to provide a surface resistivity in a dissipative range; and
a second filler dispersed in the engineering plastic matrix, the second filler comprising carbon nanotubes present in an amount to provide a surface resistivity in the dissipative range,
wherein the first filler and the second filler are present in a combined amount that is insufficient to cause surface peeling or flaking from the composite material.

2. The composite material of claim 1, wherein the engineering plastic comprises polyether ether ketone (PEEK), liquid crystal polymer (LCP), polyphenylene sulfide (PPS), polycarbonate (PC), polysulfone (PSU), polyetherimide(PEI), polyoxymethylene (POM), polyamide (Nylon), polyethylene terephthalate (PET), polybutylene terephthalate (PBT), or blends or combinations thereof.

3. The composite material of claim 1, wherein the first filler comprises long carbon fibers, short carbon fibers, or a combination of long and short carbon fibers.

4. The composite material of claim 1, wherein the second filler comprises single-walled carbon nanotubes, multi-walled carbon nanotubes, graphene, carbon nanofibers, or any combination thereof.

5. The composite material of claim 1, wherein the first filler is present in an amount of 5% to 20% by weight in the composite material.

6. The composite material of claim 1, wherein the first filler is present in an amount sufficient to achieve a flexural modulus for stiffness that is greater than about 10,000 MPa.

7. The composite material of claim 1, wherein the second filler is present in an amount of 0.1% to 8% by weight in the composite material.

8. The composite material of claim 1, wherein the second filler is present in an amount sufficient to achieve a surface resistivity of about 1×10⁴ ohms to 9.9×10¹¹ ohms.

9. The composite material of claim 1, wherein the engineering plastic matrix comprises PEEK, the first filler is present in an amount of no more than 20% by weight, and the second filler is present in an amount of 0.1% to 8% by weight.

10. A molded tray for containing electronic components in a plurality of pockets, the molded tray comprising the composite material of claim 1.

11. The molded tray of claim 10, wherein the molded tray has a heat deflection temperature of greater than about 220° C. at 1.8 MPa.

12. The molded tray of claim 10, wherein the molded tray has a flexural modulus for stiffness that is greater than about 10,000 MPa.

13. The molded tray of claim 10, wherein the molded tray has a surface resistivity of about 1×10⁴ ohms to 9.9×10¹¹ ohms.

14. The molded tray of claim 10, wherein the pockets have roughened surfaces characterized by resin-rich islands that are substantially devoid of carbon fibers.

15. The molded tray of claim 10, further comprising a plurality of through holes, each of the through holes extending from one of the plurality of pockets to an exterior surface of the molded tray.

16. The molded tray of claim 15, wherein the through holes are configured to facilitate draining of liquid during washing of electronic components contained in the pockets.

17. The molded tray of claim 15, wherein the through holes are configured to facilitate vacuum suction of electronic components contained in the pockets.

18. A method for making a molded tray for containing electronic components in a plurality of pockets, the method comprising:
blending a composite material comprising a resin composed of an engineering plastic matrix, a first filler dispersed in the engineering plastic matrix, the first filler comprising carbon fibers present in an amount to provide a desired stiffness and insufficient to provide a surface resistivity in the dissipative range, and a second filler dispersed in the engineering plastic matrix, the second filler comprising carbon nanotubes present in an amount to provide a surface resistivity in the dissipative range, wherein the first filler and the second filler are present in a combined amount that is insufficient to cause surface peeling or flaking from the composite material; and
molding the composite material to form the molded tray.

19. The method of claim 18, wherein the step of molding comprises using a mold having a roughened surface, the roughened surface configured to impart resin-rich islands on surfaces of the plurality of pockets.

20. The method of claim 18, further comprising the step of forming the roughened surface of the mold using electrical discharge machining.
